(19) United States
(12) Patent Application Publication
(10) Pub. No.: US 2025/0140623 A1
(43) Pub. Date: May 1, 2025

(54) HIGH-TEMPERATURE WIDE BANDGAP POWER MODULE AND PREPARATION METHOD THEREOF

(71) Applicant: Huazhong University of Science and Technology, Wuhan (CN)

(72) Inventors: Zhiqiang WANG, Wuhan (CN); Yunchan WU, Wuhan (CN); Rong ZHANG, Wuhan (CN); Guoqing XIN, Wuhan (CN); Xiaojie SHI, Wuhan (CN)

(73) Assignee: Huazhong University of Science and Technology, Wuhan (CN)

(21) Appl. No.: 18/397,980

(22) Filed: Dec. 27, 2023

(30) Foreign Application Priority Data
Oct. 26, 2023 (CN) 202311412601.9

(51) Int. Cl. H01L 23/31; H01L 23/04; H01L 23/29; H01L 25/00; H01L 25/18

(52) U.S. Cl. CPC H01L 23/3135; H01L 23/291; H01L 23/293; H01L 25/18; H01L 25/50; H01L 23/04

(57) ABSTRACT

A high-temperature wide-bandgap power module and a preparation method thereof is provided in the present application. In the high-temperature wide-bandgap power module, SiC power chips are arranged in the cavity, and bonding wires are used to establish electrical connections. An ultrathin composite conformal coating consists of inorganic film and Parylene-HT film is arranged on the surface of the circuit to provide long-term reliable insulation while only imposing minor thermo-mechanical stresses on bonding joint at high-temperatures, which prolongs the module's life time. In addition, the hermetic sealing adopted in the present application blocks the external water, oxygen and chemical pollution, thereby alleviating the thermal degradation of the conformal coating and safeguards the internal circuit. Overall, the hermetic sealing and conformal coating ensure the long-term 250 degrees high-temperature working capability of the wide-bandgap power module.

### CROSS-REFERENCE TO RELATED APPLICATIONS

The application claims priority to Chinese patent application No. 202311412601.9, filed on Oct. 26, 2023, the entire contents of which are incorporated herein by reference.

### TECHNICAL FIELD

The present application relates to the technical field of semiconductor module packaging, and in particular to a high-temperature wide bandgap power module and a preparation method thereof.

### BACKGROUND

A high-temperature wide bandgap power module has broad application prospects in many fields with harsh working environments, such as aerospace, electric vehicles and energy exploration, because of the advantages such as high critical electric field, high thermal conductivity, low on-resistance, high switching speed and low switching loss. In order to fully utilize the ability of wide bandgap modules to operate under high temperature and voltage, the packaging technology of wide bandgap power modules is developing to have high temperature tolerance, high voltage insulation, and high reliability.

Generally, in order to maintain a long-term reliable operation of power modules, it is necessary to encapsulate or inject to ensure the electrical insulation between circuit components, provide mechanical protection for the module and prevent external chemical pollution. At present, commercial discrete modules are mostly encapsulated by epoxy molding compound, and commercial power modules are mostly encapsulated by silicone gel. It is difficult for epoxy molding compound to withstand high temperature above 200 degrees. Moreover, due to the solid state of epoxy molding compound at room temperature, it may cause significant stress on the bonding line during temperature cycling. A large volume epoxy molding compound is at risk of cracking during repeated temperature cycling, leading to the failure of insulation and depollution capabilities. A theoretical tolerance temperature of silicone gel reaches 250 degrees, and silicone gel has good performance in the temperature range of 25 degrees to 225 degrees: 1. silicone gel provides effective electrical insulation and has good resistance to external chemical corrosion. 2. The glass transition temperature of silicone gel is low, and it presents a soft gel state at room temperature, which makes the silicone gel not produce too much stress on the bonding wire during the temperature cycle, and is beneficial to the long-term reliability of commercial power modules.

However, it is difficult for silicone gel to provide long-term effective protection for power modules under extreme high temperature conditions, that is, operating above 250 degrees; 1. silicone gel expands with the increase of temperature, which leads to the decrease of its dielectric strength. Under extreme high temperature, the insulation capacity of silicone gel is significantly weaker than the insulation capacity under normal temperature, and the insulation becomes worse. 2. The silicone gel expands severely at extremely high temperature, which makes water, oxygen and chemical pollution enter the internal circuit, resulting in the internal circuit of the module being corroded by external water, oxygen and ions. 3. silicone gel is an organic substance, and the closer the working temperature is to the theoretical tolerance temperature of the material, the faster the degradation rate is, so the thermal degradation is serious under extreme high temperature conditions, that is, above 250 degrees; in addition, because the potting materials in commercial power modules are usually directly exposed to air, the water and oxygen further promote the thermal degradation of silicone gel. 4. With the increase of service time under extreme high temperature conditions, a cross-linking density of silicone gel gradually increases, and the gel hardens; further, hardening and severe thermal expansion at high temperatures cause stress hazards to the bonding wire; repeated extreme high and low temperature cycles may lead to severe cracking of the hardened gel, resulting in the loss of insulation, anti fouling, and mechanical protection capabilities of the gel.

In order to solve the above problems, it is particularly important to design a high-temperature wide bandgap power module which may provide long-term effective insulation, mechanical protection and prevent external pollution for extreme high-temperature working conditions (that is, the temperature is above 250 degrees) and wide temperature cycle working conditions.

### SUMMARY

In view of this, a high-temperature wide bandgap power module and a preparation method thereof are provided according to the present application, so as to solve the defects existing in the conventional technology.

In a first aspect, a high-temperature wide bandgap power module is provided according to the present application, including:
a cavity in which a SiC MOSFET chip and a SiC SBD chip are arranged, a lead terminal is arranged outside the cavity, the SiC MOSFET chip and the SiC SBD chip are electrically connected with the lead terminals respectively;
a Parylene-HT® (fluorinated poly-p-xylylene) thin film layer located within the cavity and covering the SiC MOSFET chip and SiC SBD chip;
an inorganic thin film layer located on the Parylene-HT® thin film layer.

Preferably, in the high-temperature wide bandgap power module, the inorganic thin film layer is made of aluminum oxide or silicon oxide.

Preferably, in the high-temperature wide bandgap power module, a thickness of the Parylene-HT® thin film layer is 5-15 μm.

Preferably, in the high-temperature wide bandgap power module, a thickness of the inorganic thin film layer is 80-100 nm.

Preferably, in the high-temperature wide bandgap power module, a gold coating or a nickel coating is further provided on an outer surface of the cavity.

Preferably, in the high-temperature wide bandgap power module, the cavity includes:
a housing, wherein an inside of the housing is hollow, and one side of the housing is open;
a sealing plate covering the open side of the housing and sealing the housing;
a substrate is arranged in the housing, and both the SiC MOSFET chip and the SiC SBD chip are soldered on the substrate;
the lead terminal is located outside the housing.

In a second aspect, a preparation method of the high-temperature wide bandgap power module is further provided according to the present application, which includes the following steps:
providing a housing, wherein a substrate is arranged in the housing, and lead terminals are arranged outside the housing;
respectively soldering a SiC MOSFET chip and a SiC SBD chip on the substrate;
electrically connecting the SiC MOSFET chip and the SiC SBD chip with the lead terminal;
depositing a Parylene-HT® film inside the housing to obtain a Parylene-HT® film layer, the Parylene-HT® film layer covers the SiC MOSFET chip and the SiC SBD chip;
depositing an inorganic film on the surface of the Parylene-HT® film layer to obtain an inorganic film layer;
under inert gas protection or vacuum environment, the sealing plate is airtight sealed onto the housing to seal the housing.

Preferably, in the preparation method of the high-temperature wide bandgap power module, the Parylene-HT® thin film is deposited in the housing by chemical vapor deposition method with fluorinated para-xylene as raw material.

Preferably, in the preparation method of the high-temperature wide bandgap power module, aluminum oxide or silicon oxide is used as a target, and an inorganic film is deposited on the surface of the Parylene-HT® film layer by a magnetron sputtering method;

Preferably, in the preparation method of the high-temperature wide bandgap power module, in a nitrogen environment, a parallel seam welding method is used to hermetic seal the sealing plate onto the housing to seal the housing.

Preferably, the preparation method of the high-temperature wide bandgap power module further includes depositing a gold coating or a nickel coating on the surface of the housing and the sealing plate.

The present application has the following beneficial effects compared to conventional technology:
1. In the high-temperature wide bandgap power module of the present application, a Parylene-HT® thin film layer is arranged in the cavity, the Parylene-HT® thin film layer covers SiC MOSFET chips and SiC SBD chips, an inorganic thin film layer is arranged on the surface of the Parylene-HT® thin film layer, and the inorganic thin film layer and the Parylene-HT® thin film layer are compounded to form a conformal coating with high temperature tolerance and strong insulation; the Parylene-HT® thin film layer used in the present application has a much lower thermal expansion coefficient than the silicone gel; in addition, an inorganic film layer is arranged on the surface of the Parylene-HT® thin film layer, which further reduces the thermal expansion coefficient of the composite conformal coating, so that the expansion of the conformal coating is far lower than the expansion of the silicone gel at high temperature; meanwhile, the insulation performance of the Parylene-HT® thin film layer of the present application slightly decreases at high temperature, but compared with silicone gel, the insulation performance of the Parylene-HT® thin film layer at high temperature does not decrease as much as the insulation performance of silicone gel; moreover, the method of using hermetic sealing in the present application involves welding the sealing plate onto the housing to seal the housing, and the hermetic sealing provides mechanical protection for the internal circuit, which blocks the external water, oxygen and chemical pollution, alleviates the thermal degradation of the conformal coating, and further improves the working stability of the module;
2. In the preparation method of the high-temperature wide bandgap power module of the present application, by chemical vapor deposition (CVD), a layer of Parylene-HT® thin film (the film thickness is determined by the module voltage level) is evaporated on an inner surface of the power module, the substrate, the SiC MOSFET chip and the SiC SBD chip. Subsequently, a highly dense inorganic thin film layer of about 90 nm is deposited on the surface of Parylene-HT® thin film by magnetron sputtering. The preparation method of the high-temperature wide bandgap power module can effectively overcome the shortcomings of traditional silicone gel encapsulation: the Parylene-HT® thin film has much lower thermal expansion coefficient than silicone gel; in addition, the dense inorganic film is deposited on the Parylene-HT® film, which further reduces the thermal expansion coefficient of the composite conformal coating, and the expansion of the conformal coating at high temperature is much lower than the expansion of the silicone gel; the insulation performance of the Parylene-HT® thin film layer of the present application slightly decreases at high temperature, but compared with silicone gel, the insulation performance of the Parylene-HT® thin film layer at high temperature is not as decreased as the insulation performance of silicone gel; moreover, the present application adopts an hermetic sealing method to weld the sealing plate onto the housing to seal the housing; hemetic packaging provides mechanical protection for internal circuits, prevents external water, oxygen and chemical pollution, alleviates the thermal degradation of conformal coating, and further improves the working stability of the module; furthermore, the present application ensures the long-term operation of the weld seam from corrosion external gold plating, and ensures air tightness by parallel seam welding, thus avoiding the internal circuit from being corroded and finally ensuring the stability of the internal circuit; as an organic substance, Parylene-HT® inevitably degrades at high temperature, fortunately, its theoretical tolerance temperature up to 450° C. which is much higher than the theoretical tolerance temperature of silicone gel (250° C.), and it has been proved that Parylene-HT® can work at 350° C. for a long time (more than 1000 hours), so its degradation rate is far lower than the degradation rate of silicone gel when it works at 250° C.; in addition, Parylene-HT® is modified by depositing inorganic thin film layer, which reduced its thermal degradation rate. At the same time, the thermal degradation rate of Parylene-HT® is further reduced because Parylene-HT® is in a nitrogen gas-tight housing, which is free from the pollution of external water, oxygen and chemicals, resulting in a further decrease in thermal degradation rate. In general, when the operating condition is above 250 degrees, the packaging structure prepared by the present application has chemical stability far higher than the chemical stability of traditional silicone gel encapsulation, which ensures the insulation ability of high-temperature wide bandgap power module for long-term high-temperature operation; the conformal coating is a chemically stable ten micron level thin layer that generates extremely slight thermal mechanical stress on the bonding line during long-term temperature cycling, ensuring the reliability of the high-temperature wide bandgap power module under long-term wide temperature range operation.

### BRIEF DESCRIPTION OF DRAWINGS

In order to provide a clearer explanation of the embodiments of the present application or the technical solutions in the conventional technology, a brief introduction is given below to the accompanying drawings required in the description of the embodiments or conventional technology. Obviously, the accompanying drawings in the following description are only some embodiments of the present application. For ordinary technical personnel in this field, other accompanying drawings can be obtained based on these drawings without any creative labor.

FIG. 1 is a schematic structural diagram of a high-temperature wide bandgap power module of the present application;

FIG. 2 is a schematic diagram of the connection between the Parylene-HT® thin film layer and the inorganic thin film layer of the present application;

FIG. 3 is a schematic structural diagram of a housing and a sealing plate of the present application;

FIG. 4 is a schematic diagram of the connection of the housing, SiC MOSFET chip and SiC SBD chip of the present application;

FIG. 5 is a schematic diagram of the connection of the SiC MOSFET chip, the SiC SBD chip and a substrate according to the present application;

FIG. 6 is a schematic structural diagram of the substrate of the present application;

FIG. 7 is a schematic diagram of the connection of the SiC MOSFET chip, the SiC SBD chip and a lead terminal according to the present application;

FIG. 8 is an explosion schematic diagram of the high-temperature wide bandgap power module of the present application;

FIG. 9 shows a characteristic diagram of a wide temperature on-state resistance of SiC MOSFET packaged in the high-temperature wide bandgap power module in the first embodiment;

FIG. 10 shows the characteristic diagram of the wide temperature output of SiC MOSFET packaged in the high-temperature wide bandgap power module in the first embodiment;

FIG. 11 shows a dynamic switching characteristics test results of the high-temperature wide bandgap power module prepared in the first embodiment;

FIG. 12 is an appearance change diagram of the module encapsulated by silicone gel during thermal shock;

FIG. 13 shows the appearance changes of the high-temperature wide bandgap power module packaged with hermetic conformal coating in the first embodiment before and after thermal shock;

FIG. 14 shows the on-state resistance changes of the module encapsulated by silicone gel and the high-temperature wide bandgap power module encapsulated by hermetic conformal coating in the first embodiment during thermal shock;

FIG. 15 shows the insulation capacity of the high-temperature wide bandgap power module encapsulated by hermetic conformal coating in the first embodiment after 500 thermal shock cycles;

FIG. 16 is a BUCK circuit diagram of a continuous operation experiment of the high-temperature wide bandgap power module encapsulated by hermetic conformal coating in the first embodiment;

FIG. 17 shows the test results of continuous operation of the high-temperature wide bandgap power module encapsulated by hermetic conformal coating in the first embodiment.

### DETAILED DESCRIPTION OF THE EMBODIMENTS

In the following, the technical scheme in the embodiment of the present application is described clearly and completely in combination with the embodiment of the present application. Obviously, the described embodiment is only a partial embodiment of the present application, not the entire embodiment. Based on the embodiment in the present application, all other embodiment obtained by ordinary technicians in the field without creative labor belong to the scope of protection of the present application.

It should be noted that the description order of the following embodiment is not taken as a limitation to the preferred order of the embodiment. In addition, in the description of this application, the term “including” means “including but not limited to”. Various embodiment of the present application may exist in a range of forms; it should be understood that the description in the form of a range is only for convenience and conciseness, and should not be construed as a rigid limitation on the scope of the present application; therefore, it should be considered that the range description has specifically disclosed all possible subranges and a single numerical value within the range. For example, it should be considered that the description of the range from 1 to 6 has included specific disclosed subranges, such as from 1 to 3, from 1 to 4, from 1 to 5, from 2 to 4, from 2 to 6, from 3 to 6, etc., and single numbers within the range, such as 1, 2, 3, 4, 5 and 6, this interpretation is applicable regardless of the range. In addition, whenever a numerical range is indicated in this article, it refers to any referenced numbers (fractions or integers) within the range.

It should be noted that like reference numerals and letters indicate like items in the following drawings, therefore, once an item is defined in one drawing, it does not need to be further defined and explained in subsequent drawings.

In the description of the present application, it should be understood that the relationship indicating the orientation or position such as “up” is based on the orientation or position shown in the attached drawings, or the orientation or position that the product of the invention is usually placed when used, or the orientation or position that is commonly understood by those skilled in the art, is only for the convenience of describing the present application and simplifying the description, and does not indicate or imply that the equipment or elements referred to must have a specific orientation, be constructed and operated in a specific orientation, so it cannot be understood as limiting the present application.

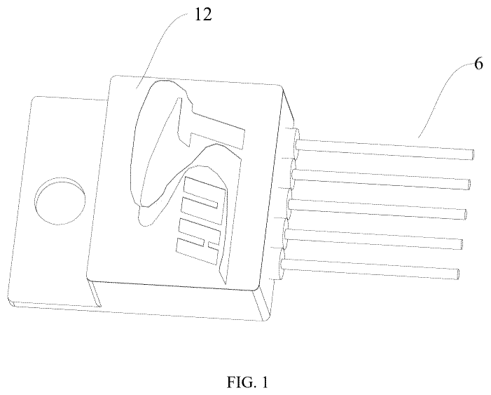

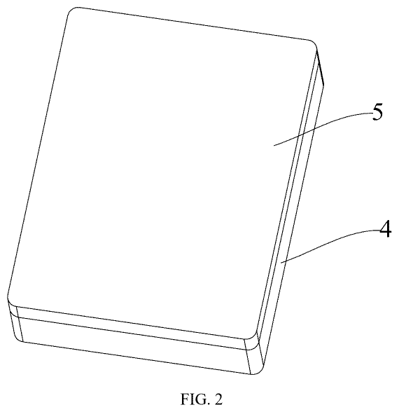

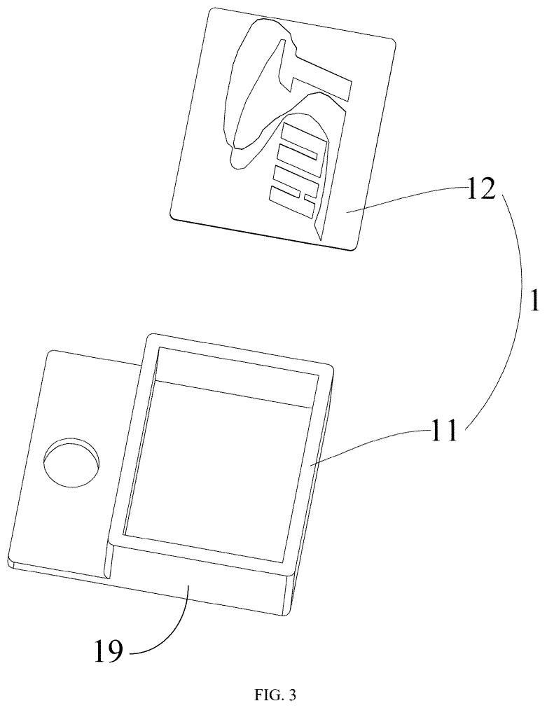

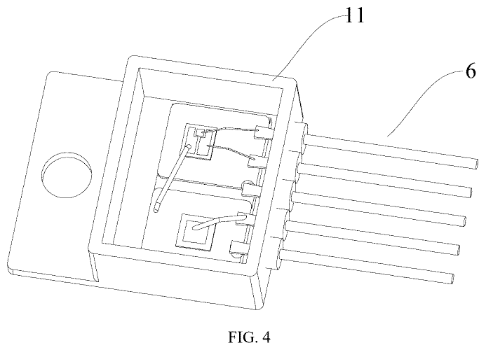

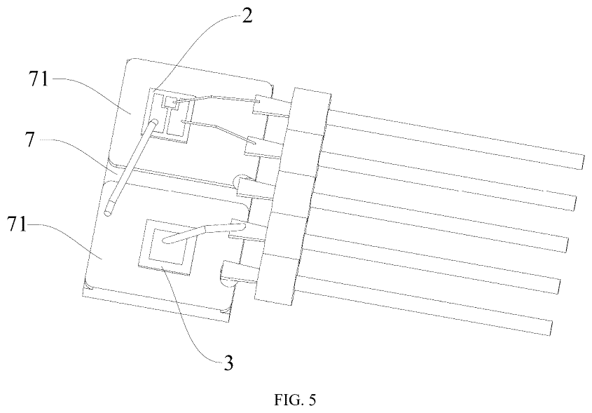

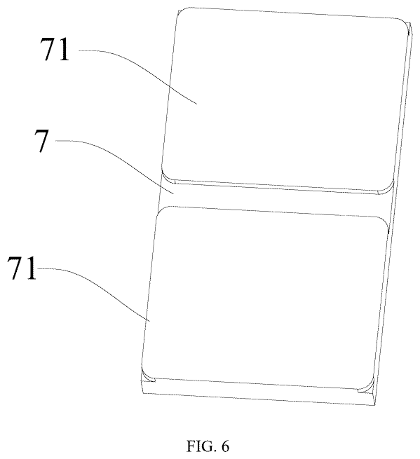

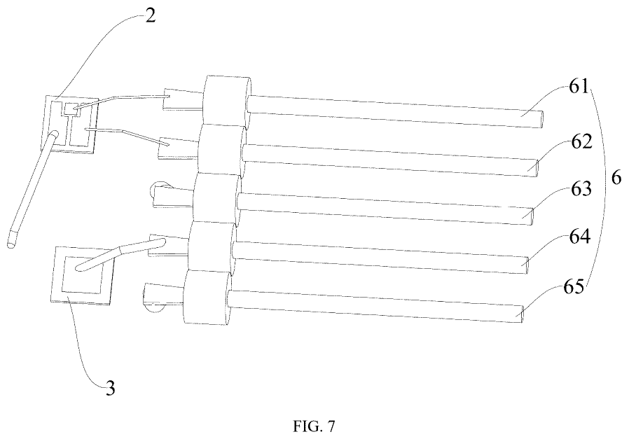

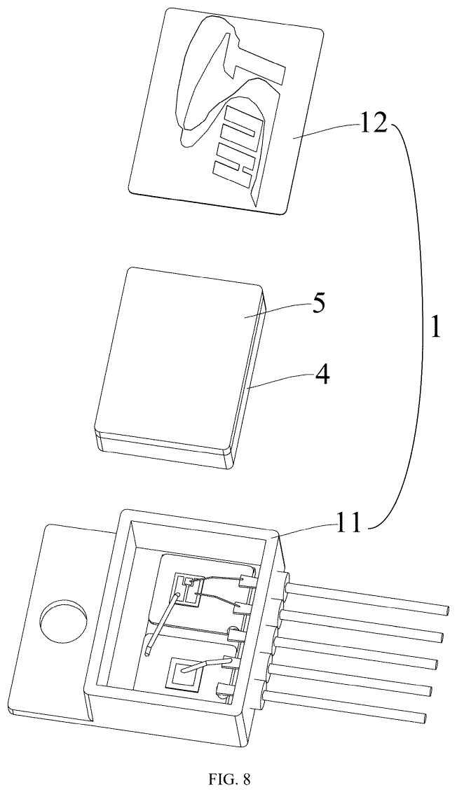

A high-temperature wide bandgap power module is provided according to an embodiment of the present application, as shown in FIG. 1 to FIG. 8, including:
a cavity 1 in which a SiC MOSFET chip 2 and a SiC SBD chip 3 are arranged, a lead terminal is arranged outside the cavity, the SiC MOSFET chip 2 and the SiC SBD chip 3 are electrically connected with the lead terminals 6 respectively;
a Parylene-HT® thin film layer 4 located within the cavity and covering the SiC MOSFET chip 2 and SiC SBD chip 3;
an inorganic thin film layer 5 located on the Parylene-HT® thin film layer 4.

It should be noted that the high-temperature wide bandgap power module of the present application includes a cavity 1, a SiC MOSFET chip 2, and a SiC SBD chip 3, the SiC MOSFET chip 2 and the SiC SBD chip 3 are both located in the cavity 1, the SiC MOSFET chip 2 and the SiC SBD chip 3 are all conventional commercial chips, and the present application does not improve the SiC MOSFET chip 2 and the SiC SBD chip 3; the SiC MOSFET chip 2 and the SiC SBD chip 3 are both electrically connected with the lead terminal 6, so that the lead terminal 6 is electrically connected with the internal circuits of the SiC MOSFET chip 2 and the SiC SBD chip 3. a Parylene-HT® thin film layer 4 is arranged in the cavity 1, the Parylene-HT® thin film layer 4 covers SiC MOSFET chips 2 and SiC SBD chips 3, an inorganic thin film layer 5 is arranged on the surface of the Parylene-HT® thin film layer 4, and the inorganic thin film layer 5 and the Parylene-HT® thin film layer 4 are compounded to form a conformal coating with high temperature tolerance and strong insulation; the Parylene-HT® thin film layer 4 used in the present application has a much lower thermal expansion coefficient than the silicone gel; in addition, an inorganic film layer 5 is arranged on the surface of the Parylene-HT® thin film layer 4, which further reduces the thermal expansion coefficient of the composite conformal coating, so that the expansion of the conformal coating is far lower than the expansion of the silicone gel at high temperature; meanwhile, the insulation performance of the Parylene-HT® thin film layer of the present application slightly decreases at high temperature, but compared with silicone gel, the insulation performance of the Parylene-HT® thin film layer at high temperature does not decrease as much as the insulation performance of silicone gel.

In some embodiment, the material of the inorganic thin film layer 5 is aluminum oxide or silicon oxide.

In some embodiment, a thickness of Parylene-HT® thin film layer 4 is determined by the module voltage level, Specifically, the thickness of Parylene-HT® film layer 4 is 5-15 μm.

Specifically, Parylene-HT®, product name: Parylene-HT® powder, Chinese name: fluorodimer para xylene, Chinese alias: Parylene-HT®, English name: Parylene-HT®.

In some embodiments, a thickness of the inorganic thin film layer 5 is 80 to 100 nm.

In some embodiments, a gold or nickel coating is further provided on an outer surface of the cavity 1.

In some embodiments, the cavity 1 includes:
a housing 11, wherein an inside of the housing 11 is hollow, and one side of the housing 11 is open;
a sealing plate 12 covering the open side of the housing 11 and sealing the housing;
Both SiC MOSFET chip 2 and SiC SBD chip 3 are located inside the housing 11.

In some embodiment, a substrate 7 is arranged in the housing 11, and both the SiC MOSFET chip 2 and the SiC SBD chip 3 are soldered on the substrate 7. Lead terminals 6 are arranged outside the housing 11.

Specifically, the substrate 7 is a ceramic substrate on which copper sheets 71 are spaced apart. The SiC MOSFET chip 2 and the SiC SBD chip 3 are welded to the copper sheet 71, respectively.

In some embodiment, the lead terminal 6 includes a gate lead terminal 61, a Kelvin source lead terminal 62, a DC+ lead terminal 63, a DC− lead terminal 64, and an AC lead terminal 65.

The SiC MOSFET chip 2 is electrically connected to a gate lead terminal 61 and a Kelvin source lead terminal 62.

SiC SBD chip 3 is electrically connected to DC+ lead terminal 63, DC− lead terminal 64 and AC lead terminal 65.

Specifically, the gate lead terminal 61 is connected to a gate pad of the SiC MOSFET chip 2 through a bonding wire, the kelvin source lead terminal 62 is connected to a source pad of the SiC MOSFET chip 2 by a bonding wire, the DC+ lead terminal 63 is connected downwards to the copper sheet on the substrate 7 where the drain of SiC MOSFET chip 2 is located; the DC lead terminal 64 is connected to an anode pad of SiC SBD chip 3 through a bonding wire, and the AC lead terminal 65 is connected downwards to the copper sheet on the substrate 7 where the cathode of SiC SBD chip 3 is located. In some embodiment, the SiC MOSFET chip 2 is embodied as CREE CPM3-1200-0075A.

In some embodiment, the SiC SBD chip 3 is embodied as ROHM S6306.

Based on the same inventive concept, a preparation method of the high-temperature wide bandgap power module is further provided according to the present application, which includes the following steps:
S1, providing a housing, wherein a substrate is arranged in the housing, and lead terminals are arranged outside the housing;
S2, respectively soldering a SiC MOSFET chip and a SiC SBD chip on the substrate;
S3, electrically connecting the SiC MOSFET chip and the SiC SBD chip with the lead terminal;
S4, depositing a Parylene-HT® film inside the housing to obtain a Parylene-HT® film layer, the Parylene-HT® film layer covers the SiC MOSFET chip and the SiC SBD chip;
S5, depositing an inorganic film on the surface of the Parylene-HT® film layer to obtain an inorganic film layer;
S6, under inert gas protection or vacuum environment, the sealing plate is hermetic sealed onto the housing to seal the housing.

In some embodiment, the sealing plate is welded to the housing by hermetic sealing to seal the housing.

In some embodiment, in a nitrogen environment, parallel seam welding method is used to airtight seal the sealing plate onto the housing to seal the housing.

In some embodiment, the Parylene-HT® thin film is deposited in the housing by chemical vapor deposition method with fluorinated para-xylene as raw material.

Specifically, the process of depositing Parylene-HT® thin films inside the housing using chemical vapor deposition method and obtaining Parylene-HT® thin films using CVD method is as follows: at 150-175° C., Parylene dimer solid is vaporized into Parylene dimer gas; subsequently, at 650-690° C., Parylene dimer gas is pyrolyzed into monomer gas; finally, at room temperature, the monomer is deposited in the housing to form Parylene-HT® thin film, which covers the substrate, SiC MOSFET chip and SiC SBD chip. In some embodiment, aluminum oxide or silicon oxide is used as the target, and inorganic thin films are deposited on the surface of Parylene-HT® thin film layer by magnetron sputtering.

Specifically, the technological process of preparing aluminum oxide film or silicon oxide film by magnetron sputtering is as follows: the target material is high-purity alumina target or silica target, which is sputtered for 2-4 hours at a sputtering power of 50-100 W, thus forming a compact alumina film or silica film on the surface of Parylene-HT® film.

In some embodiment, the preparation method of the high-temperature wide bandgap power module further includes depositing a gold layer on the surface of the housing and the sealing plate.

Specifically, a gold coating or a nickel coating, which is obtained by electroplating deposition, is also deposited on the surface of the lead terminal. Gold coating or nickel coating deposited on the surface of the housing may prevent weld corrosion and enhance weldability.

Specifically, under the protection of inert gas or vacuum environment, the sealing plate is welded to the housing to seal the housing. The inert gas includes but is not limited to nitrogen, helium, neon, argon, etc., preferably nitrogen, and parallel seam welding method is used for airtight sealing in nitrogen environment. It can be understood that due to the gas sealing welding under inert gas, after the sealing plate is welded to the housing, the housing is filled with a certain amount of inert gas, such as nitrogen.

Specifically, the external lead terminal passes through the metal housing, and the lead terminal is connected with the internal circuits of the SiC MOSFET chip and the SiC SBD chip by bonding wires or other electrical interconnection methods; the SiC MOSFET chip and the SiC SBD chip are connected with the substrate through nano-silver sintering or high-temperature solder vacuum reflow soldering; the substrate is fixed in the housing by sintering or vacuum reflow soldering; finally, reliable electrical connections are formed between the components to form a complete electrical circuit of the power module. The present application has no special requirements on the component material, topological structure, current grade and the like of the power module, and has wide applicability.

A core of the present application is that: by chemical vapor deposition (CVD), a layer of Parylene-HT® thin film is deposited on the inner surface of the power module housing, substrate, SiC MOSFET chip, and SiC SBD chip surfaces (the thickness of the film is determined by the module voltage level); subsequently, a highly dense inorganic thin film layer is deposited on the surface of Parylene-HT® thin film by magnetron sputtering, the material of the thin film layer may be aluminum oxide or silicon oxide, inorganic thin films are combined with Parylene-HT® thin films to form a conformal coating with high temperature tolerance and strong insulation. Subsequently, the power module is sealed by welding in a nitrogen or vacuum environment to ensure that all components and conformal coatings of the power module are in a stable nitrogen or vacuum environment during operation. Finally, the outer surface of the metal housing after hermetic seal is plated with gold or nickel to prevent the weld seam from being corroded, and the solderability of the lead terminal is enhanced, which is convenient for its connection with external circuits.

The preparation method of the high-temperature wide bandgap power module may effectively overcome the shortcomings of traditional silicone gel encapsulation: 1. The Parylene-HT® thin film layer used in the present application has a much lower thermal expansion coefficient than the silicone gel; in addition, an inorganic film layer is arranged on the surface of the Parylene-HT® thin film layer, which further reduces the thermal expansion coefficient of the composite conformal coating, so that the expansion of the conformal coating is far lower than the expansion of the silicone gel at high temperature; meanwhile, the insulation performance of the Parylene-HT® thin film layer of the present application slightly decreases at high temperature, but compared with silicone gel, the insulation performance of the Parylene-HT® thin film layer at high temperature does not decrease as much as the insulation performance of silicone gel; 2. The hermetic sealing provides mechanical protection for the internal circuit, and blocks the external water, oxygen and chemical pollution, alleviates the thermal degradation of the conformal coating, and further improves the working stability of the module; furthermore, the present application ensures the long-term operation for protecting the weld seam from corrosion by external gold plating, and ensuring air tightness by parallel seam welding, thus avoiding the internal circuit from being corroded and finally ensuring the stability of the internal circuit; 3. As an organic substance, Parylene-HT® inevitably degrades at high temperature, fortunately, its theoretical tolerance temperature up to 450° C., which is much higher than the theoretical tolerance temperature of silicone gel (250° C.), and it has been proved that Parylene-HT® can work at 350° C. for a long time (more than 1000 hours), so when it works at 250° C., its degradation rate is far lower than the degradation rate of silicone gel; in addition, Parylene-HT® is modified by depositing inorganic thin film layers, which further reduced its thermal degradation rate. At the same time, the thermal degradation rate of Parylene-HT® is further reduced because Parylene-HT® is in a nitrogen hermetic housing, which is free from the pollution of external water, oxygen and chemicals, resulting in a further decrease in thermal degradation rate. In general, when the operating condition is above 250 degrees, the packaging structure prepared by the present application has chemical stability far higher than the chemical stability of traditional silicone gel encapsulation, which ensures the insulation ability of high-temperature wide bandgap power module for long-term high-temperature operation; 4. The conformal coating is a chemically stable ten micron level thin layer that generates extremely slight thermal mechanical stress on the bonding wires during long-term temperature cycling, ensuring the reliability of the high-temperature wide bandgap power module during long-term wide temperature range operation. 5. Covering the weld with gold plating on the housing may effectively prevent the weld from being corroded, and further prevent the external water, oxygen and chemical pollution from infiltrating into the hermetic cavity, thus ensuring long-term stability of the internal environment.

The following further illustrates the preparation method of the high-temperature wide bandgap power module of the present application with specific embodiments. This part further illustrates the content of the present application with specific examples, but it should not be understood as limiting the present application. Unless otherwise specified, the technical means used in the embodiments are conventional means well known to those skilled in the art. Unless otherwise specified, the reagents, methods and equipment used in the present application are conventional reagents, methods and equipment in this field.

### First Embodiment

A preparation method of a high-temperature wide bandgap power module is provided according to the embodiment of the present application, which includes the following steps:
S1, providing a housing, wherein one side of the housing is open, a ceramic substrate (specifically a beryllium oxide ceramic substrate) is arranged in the housing, and a lead terminal is arranged outside the housing; lead terminals include gate lead terminals, Kelvin source lead terminals, DC+ lead terminals, DC− lead terminals and AC lead terminals;
S2, soldering a SiC MOSFET chip (specifically CREE CPM3-1200-0075A) and a SiC SBD chip (specifically ROHM S6306) on two copper sheets of a ceramic substrate by vacuum reflow soldering using tin-lead-silver solder (melting point 295 degrees);
S3, respectively electrically connecting the lead terminal with the SiC MOSFET chip and the SiC SBD chip through aluminum bonding wires;
the gate lead terminal is connected to a gate pad of the SiC MOSFET chip through a bonding wire, the kelvin source lead terminal is connected to a source pad of the SiC MOSFET chip by a bonding wire, the DC+ lead terminal is connected downwards to the copper sheet on the substrate where the drain of SiC MOSFET chip is located; the DC− lead terminal is connected to an anode pad of SiC SBD chip through a bonding wire, and the AC lead terminal is connected downwards to the copper sheet on the substrate where the cathode of SiC SBD chip is located;
S4, depositing a Parylene-HT® thin film in the housing by chemical vapor deposition (CVD) to obtain a Parylene-HT® thin film layer. Parylene-HT® thin film layer covers SiC MOSFET chip, SiC SBD chip and ceramic substrate; a thickness of Parylene-HT® thin film layer is 10 μm; the technological process of depositing Parylene-HT® thin films by CVD is as follows: at 160° C., Parylene dimer solid vaporizes into Parylene dimer gas; subsequently, at 670° C., Parylene dimer gas is pyrolyzed into monomer gas; finally, at room temperature, monomer gas is deposited on the inner surface of the housing to form Parylene-HT® thin film;
S5, depositing an alumina thin film on the surface of the Parylene-HT® thin film layer to obtain an inorganic thin film layer; a thickness of the alumina thin film is 90 nm; the technological process of preparing alumina thin film by magnetron sputtering is as follows: the target material is a high purity alumina target, which is sputtered at 60 W sputtering power for 3 hours, thus forming a dense alumina thin film on the surface of Parylene-HT® thin film;
S6, hermetically sealing the opening of the sealing plate and the housing by adopting a parallel seam welding method in a nitrogen environment, so as to seal the housing;
S7, electroplating gold on the outer surface of the housing and the sealing plate.

### Performance Test

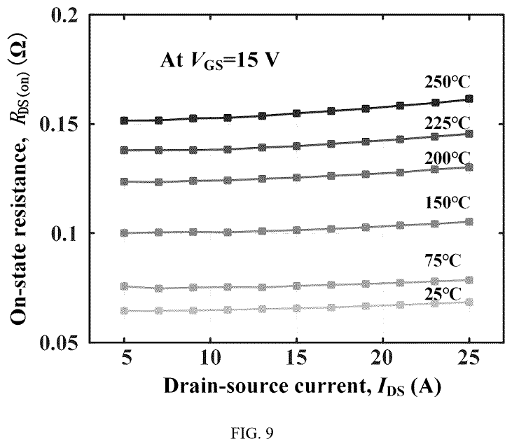

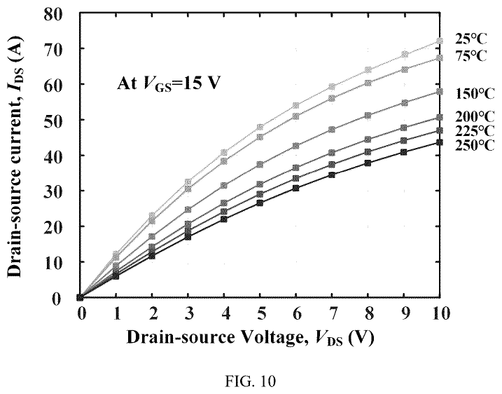

The wide temperature range static characteristics of the SiC MOSFET packaged in the first embodiment are measured through the external lead terminals of the power module, and the results are shown in FIG. 9 to FIG. 10.

Specifically, FIG. 9 is a wide temperature on-state resistance characteristic diagram of SiC MOSFET, and FIG. 10 is a wide temperature output characteristic diagram of SiC MOSFET.

Compared with the data sheet (CREE CPM3-1200-0075A), it can be seen that the package used in the present application does not significantly reduce the chip performance.

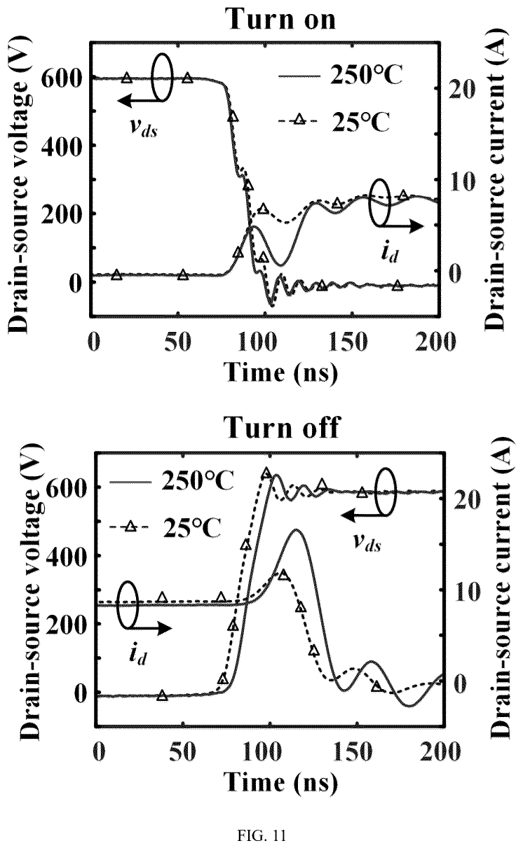

A dual pulse test platform (DPT) is built to test the dynamic operation capability of the high temperature wide bandgap power module prepared in the first embodiment. The test voltage is 600V, the test current is 10 A, and the test temperature is 25 degrees and 250 degrees. The test results are shown in FIG. 11.

As can be seen from FIG. 11, the high-temperature wide bandgap power module prepared in the first embodiment has the ability to switch at 600V and 250 degrees.

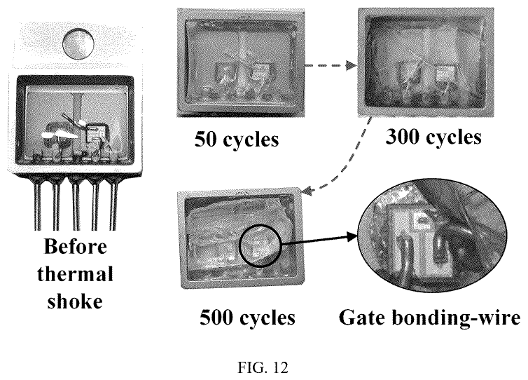

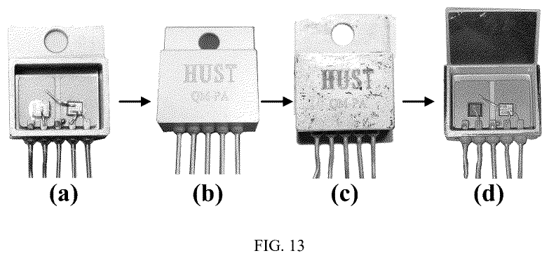

A high and low temperature thermal shock test platform of −55 to 250 degrees is built, a long-term reliability test of the high-temperature wide band gap power module encapsulated by hermetic conformal coating in the first embodiment is carried out, and another wide band gap power module is encapsulated by using silicone gel (that is, silicone gel NuSil™ R-2188 is poured into the housing during the preparation process) as a comparison. The number of thermal shock cycles is set to 500, and the module stays in the cold and hot cavity for 10 min each time. The appearance changing of the module encapsulated by silicone gel during thermal shock is shown in FIG. 12. The appearance changing of the high-temperature wide bandgap power module encapsulated by hermetic conformal coating in the first embodiment before and after thermal shock is shown in FIG. 13.

In FIG. 13, (a) is the internal view of the module housing before hermetic sealing welding, (b) is the external view of the module before thermal shock test, (c) is the external view of the module after thermal shock test, and (d) is the internal view of the module after thermal shock test.

It can be seen from FIG. 12 that during the thermal shock process of the module encapsulated with silicone gel, the gel hardened, cracked and peeled off from the module. After the thermal shock, the broken gel is clipped out with tweezers, and it is observed that the internal gate bonding wire lift off during the thermal shock.

As can be seen from FIG. 13, after thermal shock, the high-temperature wide bandgap power module encapsulated by hermetic conformal coating in the first embodiment has intact internal structure and no obvious change.

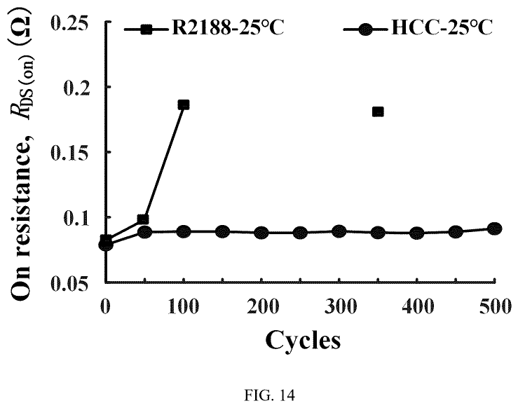

During the thermal shock process, the on-state resistance of the module encapsulated by the silicone gel and the high-temperature wide bandgap power module encapsulated by the hermetic conformal coating in the first embodiment is monitored (tested at 25° C.), and the results are shown in FIG. 14.

In FIG. 14, HCC represents the high-temperature wide bandgap power module encapsulated by hermetic conformal coating in the first embodiment, and R2188 represents the module encapsulated by silicone gel NuSil™ R-2188.

As can be seen from FIG. 14, the on-state resistance of the high-temperature wide bandgap power module (HCC) encapsulated by the hermetic conformal coating in the first embodiment is always stable, which indicates that the power module encapsulated by the hermetic conformal coating packaging method has long-term wide temperature cycling reliability; however, due to the lift off of the gate bonding wire, the module (R2188) encapsulated with silicone gel could not measure the on-state resistance value through the lead terminals after 100 cycles of the thermal shock.

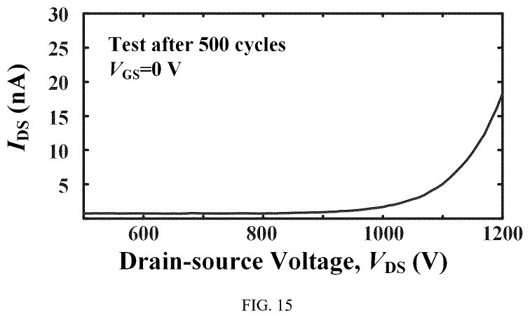

After 500 thermal shock cycles, the insulation performance of the high-temperature wide bandgap power module encapsulated by the hermetic conformal coating in the first embodiment is tested, as shown in FIG. 15, the leakage current under 1200V voltage is less than 30 nA, indicating that it still has good insulation performance.

The high temperature wide bandgap power module encapsulated by hermetic conformal coating in the first embodiment is tested by continuous operation experiment at 600V and 250 degrees.

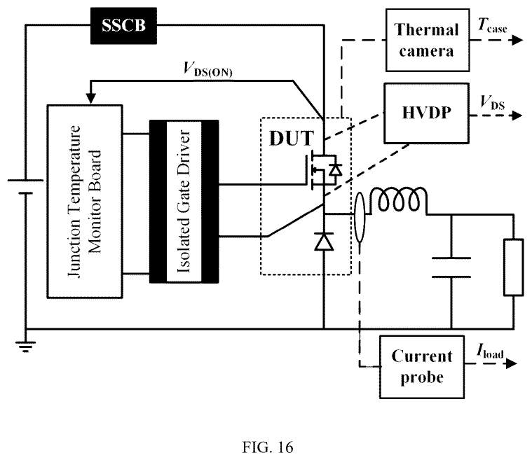

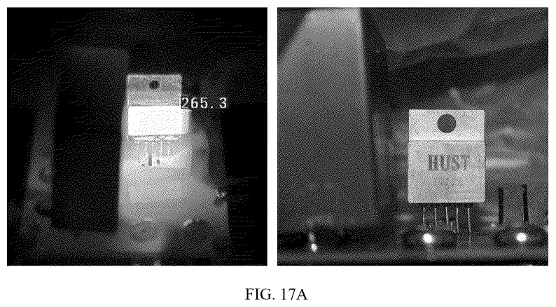

As shown in FIG. 16, the test topology is a BUCK circuit, and the input voltage is 600V DC voltage. A solid-state circuit breaker SSCB is used to protect the circuit in case of short circuit fault. By using the isolated gate driver to control the duty ratio (i.e., the proportion of conduction time to switch period), the output DC voltage is controlled, thereby achieving the effect of voltage reduction. The relationship between input voltage and output voltage is: Vₒᵤₜ=D*Vᵢₙ, where Vₒᵤₜ is the output DC voltage, Vᵢₙ is the input DC voltage, and D represents the duty ratio. The circuit heats up the chip junction temperature to over 250 degrees mainly through the conduction loss and switching loss of SiC MOSFET. The circuit maintains continuous operation, and the key parameters of the circuit operation are as follows: switching frequency 10 kHz, duty cycle 22% and input voltage 600V. Due to the fact that the chip is located inside the hermetic housing, it is not possible to directly measure the chip junction temperature using an infrared thermal imager. Therefore, the electrical parameter method (based on the on-state resistance value) is used to calculate the chip junction temperature during the conduction process, the principle is that the drain-source voltage V_{DS(ON)} of the SiC MOSFET chip is collected by the junction temperature measuring circuit board in FIG. 16, and the conduction current I_{load} is collected by the continuous current probe, and the on-state resistance value R_{DS(ON)} is calculated by the PC. According to the calculated resistance value R_{DS(ON)} and the conduction current value I_{load}, the junction temperature look-up table measured before the experiment is queried, so as to read the current junction temperature Tⱼ. The junction temperature look-up table is a conduction current—junction temperature—on-state resistance data table obtained through a curve tracer with hot plate before continuous operation of the experiment, as long as two of the values are known, the third value can be found through this table. In addition, the infrared thermal imager is used to observe the module case temperature T_{case} to prove the reliability of the calculated junction temperature: the module works under the natural convection heat dissipation condition, and the junction-ambient thermal resistance is about 20 degrees per watt, and the junction-case thermal resistance is about 1 degree per watt. As a heat source, the chip dissipates heat from the inside of the hermetic housing to the outside environment, so when the junction temperature of the chip reaches more than 250 degrees, the heating power is about ten watts, and the junction-case temperature difference should be about 20 degrees. By comparing the measured housing temperature and the calculated junction temperature, it can be roughly inferred whether the calculated junction temperature data is credible. A high-voltage differential probe is used to measure the drain-source voltage V_{DS} of the SiC MOSFET in the module and confirm that the module is operating at a voltage of 600V.

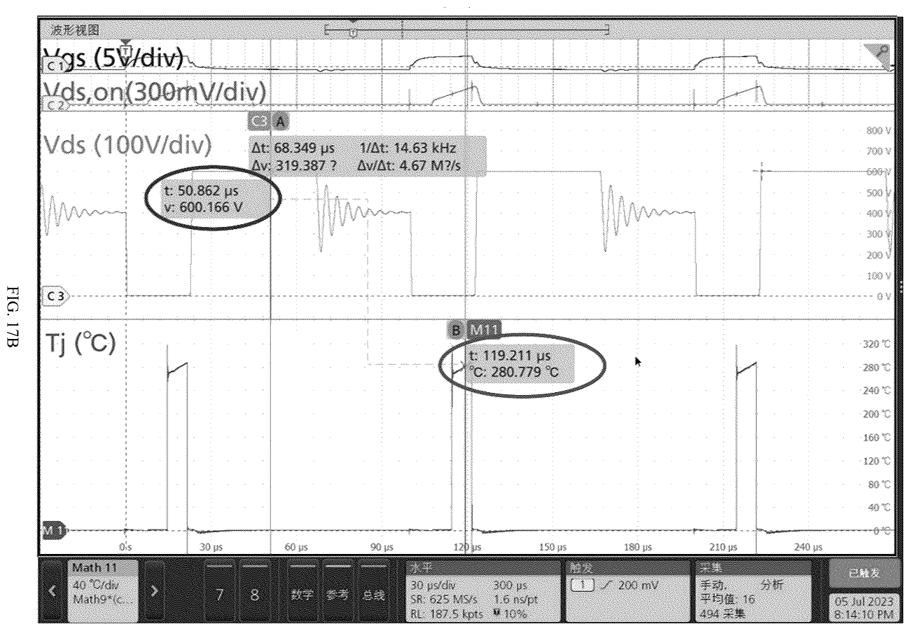

The experimental results are shown in FIG. 17, the housing temperature of the high-temperature wide bandgap power module obtained by the infrared thermal imager is 265 degrees, the real-time junction temperature of the chip calculated by the electrical parameter method is about 15 degrees higher than the housing temperature, which is 280 degrees, indicating that the highest temperature inside the power module at this time is about 280 degrees; the acquired voltage waveform indicates that the power module runs continuously under the condition of 600V voltage, and the waveform conforms to the discontinuous current operation mode (DCM) of BUCK circuit. The prepared high-temperature wide bandgap power module has been running continuously for 15 minutes under the conditions of high temperature above 250 degrees and high voltage of 600V without any abnormality. The experimental results show that the power module encapsulated by hermetic conformal coating has the ability of continuous operation at high temperature and high voltage.

To sum up, the thermal shock experiment of −55° C. to 250° C. verified that the hermetic conformal coating does have a much lower thermo-mechanical stress than silicone gel, and has the ability to operate in a wide temperature range for a long time. The continuous operation experiments at 600V and 250 degrees verify that the high-temperature wide bandgap power module encapsulated by hermetic conformal coating has the ability of continuous operation at high temperature and high voltage.

The above is only the preferred embodiment of the present application, and it is not used to limit the present application. Any modification, equivalent substitution, improvement, etc. made within the spirit and principle of the present application should be included in the protection scope of the present application.

1. A preparation method of a high-temperature wide bandgap power module, the high-temperature wide bandgap power module comprising:
a cavity in which a SiC MOSFET chip and a SiC SBD chip are arranged, wherein a lead terminal is arranged outside the cavity, the SiC MOSFET chip and the SiC SBD chip are electrically connected with the lead terminal respectively;
a fluorinated poly-p-xylylene thin film layer located within the cavity and covering the SiC MOSFET chip and the SiC SBD chip; and
an inorganic thin film layer located on the fluorinated poly-p-xylylene thin film layer;
wherein the inorganic thin film layer is made of aluminum oxide or silicon oxide;
a gold coating or a nickel coating is further provided on an outer surface of the cavity;
a thickness of the fluorinated poly-p-xylylene thin film layer is 5-15 μm;
a thickness of the inorganic thin film layer is 80-100 nm;
the cavity comprises:
a housing, wherein an inside of the housing is hollow, and one side of the housing is open;
a sealing plate covering the open side of the housing and sealing the housing;
wherein a substrate is arranged in the housing, and both the SiC MOSFET chip and the SiC SBD chip are soldered on the substrate;
wherein the lead terminal is located outside the housing;
the preparation method of the high-temperature wide bandgap power module comprising the following steps:
providing the housing, wherein the substrate is arranged in the housing, and the lead terminal is arranged outside the housing;
respectively soldering the SiC MOSFET chip and the SiC SBD chip on the substrate;
electrically connecting the SiC MOSFET chip and the SiC SBD chip with the lead terminal;
depositing a fluorinated poly-p-xylylene film inside the housing to obtain the fluorinated poly-p-xylylene film layer, the fluorinated poly-p-xylylene thin film layer covers the SiC MOSFET chip and the SiC SBD chip;
depositing an inorganic film on the surface of the fluorinated poly-p-xylylene thin film layer to obtain the inorganic thin film layer;
wherein in a nitrogen environment, a parallel seam welding method is used to airtight seal the sealing plate onto the housing to seal the housing;
further comprising depositing the gold coating or the nickel coating on a surface of the housing and the sealing plate;
wherein the lead terminal further comprises a gate lead terminal, a Kelvin source lead terminal, a DC+ lead terminal, a DC− lead terminal and an AC lead terminal;
the SiC MOSFET chip is electrically connected to the gate lead terminal and the Kelvin source lead terminal;
the SiC SBD chip is electrically connected to the DC+ lead terminal, the DC− lead terminal and the AC lead terminal;
the gate lead terminal is connected to a gate pad of the SiC MOSFET chip through a first bonding wire, the Kelvin source lead terminal is connected to a source pad of the SiC MOSFET chip by a second bonding wire, the DC+ lead terminal is connected downwards to a copper sheet on the substrate where a drain of the SiC MOSFET chip is located; the DC− lead terminal is connected to an anode pad of the SiC SBD chip through a third bonding wire, and the AC lead terminal is connected downwards to the copper sheet on the substrate where a cathode of the SiC SBD chip is located;
the high-temperature wide bandgap power module can withstand 500 high and low temperature shock tests at −55° C. to 250° C. and maintain a sealing state; the leakage current under 1200 V voltage is less than 30 nA; and the high-temperature wide bandgap power module runs continuously for 15 min under the conditions of high temperature above 250° C. and high voltage of 600 V and kept operation.

2. The preparation method of the high-temperature wide bandgap power module according to claim 1, wherein the fluorinated poly-p-xylylene thin film is deposited in the housing by chemical vapor deposition method with fluorinated para-xylene as raw material.

3. The preparation method of the high-temperature wide bandgap power module according to claim 1, wherein aluminum oxide or silicon oxide is used as a target, and the inorganic film is deposited on the surface of the fluorinated poly-p-xylylene thin film layer by a magnetron sputtering method.
